(19) United States
(12) Patent Application Publication
(10) Pub. No.: US 2025/0173558 A1
(43) Pub. Date: May 29, 2025

(54) NEUROMORPHIC DEVICE

(71) Applicant: TDK CORPORATION, Tokyo (JP)

(72) Inventors: Shogo YAMADA, Tokyo (JP); Tatsuo SHIBATA, Tokyo (JP)

(73) Assignee: TDK CORPORATION, Tokyo (JP)

(21) Appl. No.: 18/843,489

(22) PCT Filed: Mar. 4, 2022
(86) PCT No.: PCT/JP2022/009408

§ 371 Date: Sep. 3, 2024

(51) Int. Cl. G06N 3/065; G11C 13/00; G11C 19/08; H10N 50/10; H10N 70/00; H10N 70/20

(52) U.S. Cl. CPC G06N 3/065; G11C 13/004; G11C 13/0069; G11C 19/0841; H10N 50/10; H10N 70/841; G11C 2013/0045; G11C 2013/0078; H10N 70/20

(57) ABSTRACT

A neuromorphic device includes a plurality of paired elements and a control device that controls each of the plurality of paired elements. Each of the plurality of paired elements includes a first magnetoresistance effect element, a second magnetoresistance effect element, and a readout electrode shared by the first magnetoresistance effect element and the second magnetoresistance effect element. Each of the first magnetoresistance effect element and the second magnetoresistance effect element includes a reference layer, a magnetic recording layer, a non-magnetic layer, and two electrodes. The readout electrode is connected across the reference layers of the first magnetoresistance effect element and the second magnetoresistance effect element. The control device reverses a direction in which a read current flows between the first magnetoresistance effect element and the second magnetoresistance effect element in a specific paired element from which a signal is read.

### TECHNICAL FIELD

The present invention relates to a neuromorphic device.

### BACKGROUND ART

A neuromorphic device is a device that performs neural network calculations. The neuromorphic device artificially mimics a relationship between neurons and synapses in a human brain.

A neuromorphic device in which memristor elements such as a phase change memory (PCM), a resistive random access memory (ReRAM), and a domain wall movement type magnetoresistance effect element (domain wall movement element) are integrated has been proposed. The memristor element outputs a product of an input voltage and a conductance value of the memristor element as a current. The memristor element functions as a product calculation element in a product-sum calculation of the neuromorphic device. For example, Patent Document 1 describes a neuromorphic device using domain wall movement elements.

The conductance value of the memristor element corresponds to a weight at the time of learning of the neuromorphic device. Both the positive weight and the negative weight are necessary in the learning of the neuromorphic device. With a real element, it is difficult to realize negative conductance. Therefore, a method of setting two elements as a pair, assigning a positive weight and a negative weight to each element, and taking a difference has been proposed. For example, Patent Document 2 discloses a method of separating an element array into a positive value and a negative value, assigning an absolute value of a weight to each of the values, and taking a difference after product calculation.

### CITATION LIST

### Patent Document

Patent Document 1: Japanese Patent No. 6617829
Patent Document 2: International Publication No. 2018/034163

### SUMMARY OF INVENTION

### Technical Problem

It is preferable for a maximum resistance value and a minimum resistance value of a memristor element that is responsible for a positive value to be not different from a maximum resistance value and a minimum resistance value of a memristor element that is responsible for a negative value. When a maximum resistance value or a minimum resistance value is different between paired elements, an operation of determining weights for learning from a positive value and a negative value becomes complicated.

The present invention has been made in consideration of the above problem, and an object of the present invention is to provide a neuromorphic device capable of reducing a temperature difference between paired elements and reducing a variation in resistance value.

### Solution to Problem

A neuromorphic device according to a first aspect includes a plurality of paired elements and a control device configured to control each of the plurality of paired elements. Each of the plurality of paired elements includes a first magnetoresistance effect element, a second magnetoresistance effect element, and a readout electrode shared by the first magnetoresistance effect element and the second magnetoresistance effect element. The first magnetoresistance effect element includes a first reference layer, a first magnetic recording layer, a first non-magnetic layer between the first reference layer and the first magnetic recording layer, a first electrode electrically connected to the first magnetic recording layer, and a second electrode spaced apart from the first electrode and electrically connected to the first magnetic recording layer. The second magnetoresistance effect element includes a second reference layer, a second magnetic recording layer, a second non-magnetic layer between the second reference layer and the second magnetic recording layer, a third electrode electrically connected to the second magnetic recording layer, and a fourth electrode spaced apart from the third electrode and electrically connected to the second magnetic recording layer. The readout electrode is connected across the first reference layer and the second reference layer. The control device causes a first read current and a second read current to flow to a specific paired element from which a signal is read. The first read current flows in a stacking direction of the first magnetoresistance effect element and the second read current flows in the stacking direction of the second magnetoresistance effect element. When the first read current flows from the first reference layer to the first magnetic recording layer, the second read current flows from the second magnetic recording layer to the second reference layer. When the first read current flows from the first magnetic recording layer to the first reference layer, the second read current flows from the second reference layer to the second magnetic recording layer.

### Advantageous Effects of Invention

With the neuromorphic device according to the aspect, it is possible to reduce a temperature difference between paired elements and reduce a variation in resistance value.

### BRIEF DESCRIPTION OF DRAWINGS

FIG. 1 is a schematic diagram of a neural network.

FIG. 2 is a block diagram of a neuromorphic device according to a first embodiment.

FIG. 3 is a circuit diagram of a magnetic array of the neuromorphic device according to the first embodiment.

FIG. 4 is a circuit diagram of another example of the magnetic array of the neuromorphic device according to the first embodiment.

FIG. 5 is a cross-sectional view of the vicinity of a paired element according to the first embodiment.

FIG. 6 is a cross-sectional view of the paired element according to the first embodiment.

FIG. 7 is a plan view of the paired element according to the first embodiment.

FIG. 8 is another plan view of the paired element according to the first embodiment.

FIG. 9 is a view illustrating a write operation of the paired element according to the first embodiment.

FIG. 10 is a view illustrating a read operation of the paired element according to the first embodiment.

FIG. 11 is a view showing a part of a method of manufacturing the paired element according to the first embodiment.

FIG. 12 is a view showing a part of a method of manufacturing the paired element according to the first embodiment.

FIG. 13 is a view showing a part of a method of manufacturing the paired element according to the first embodiment.

FIG. 14 is a view showing a part of a method of manufacturing the paired element according to the first embodiment.

FIG. 15 is a view showing a part of a method of manufacturing the paired element according to the first embodiment.

FIG. 16 is a cross-sectional view of a paired element according to a first modification example.

FIG. 17 is a plan view of the paired element according to the first modification example.

FIG. 18 is a cross-sectional view of a paired element according to a second modification example.

FIG. 19 is a cross-sectional view of a paired element according to a third modification example.

FIG. 20 is a cross-sectional view of a paired element according to a fourth modification example.

FIG. 21 is a plan view of the paired element according to a fifth modification example.

FIG. 22 is a cross-sectional view of a paired element according to a sixth modification example.

FIG. 23 is a cross-sectional view of a paired element according to a seventh modification example.

### DESCRIPTION OF EMBODIMENTS

Hereinafter, the present embodiment will be described in detail with appropriate reference to the drawings. The drawings used in the following description may show enlarged characteristic parts for the sake of convenience in order to make the characteristics of the present invention easier to understand, and a dimensional ratio of each component or the like may differ from an actual one. Materials, dimensions, and the like illustrated in the following description are merely examples, and the present invention is not limited thereto, and may be changed appropriately within the scope in which the effects of the present invention are achieved.

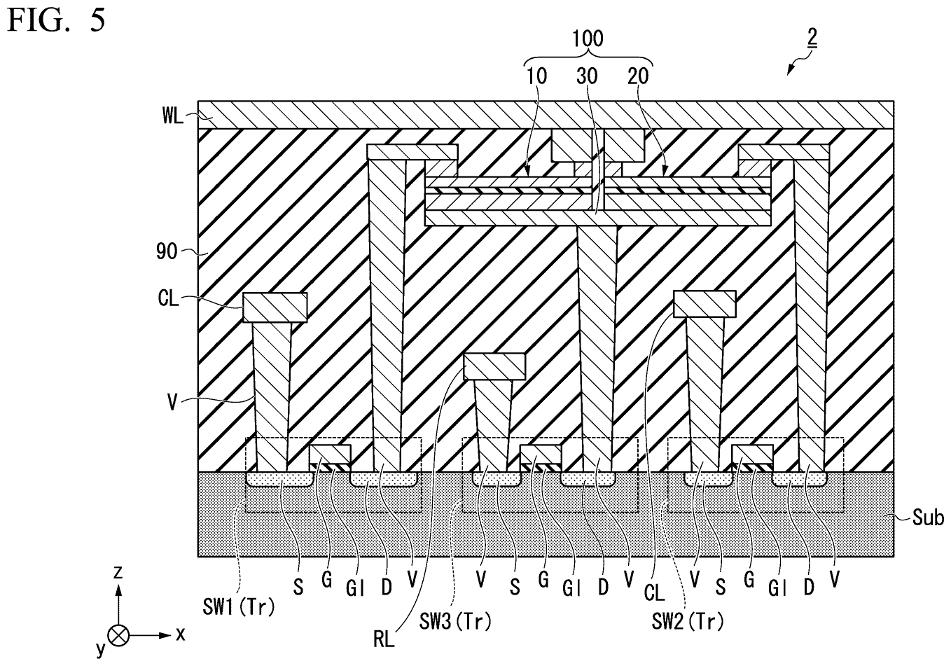

First, directions are defined. x and y directions are approximately parallel to one surface of a substrate Sub (see FIG. 5) to be described later. The x direction is, for example, a direction in which a first magnetic recording layer 13 to be described later extends. The y direction is a direction perpendicular to the x direction. A z direction is a direction from the substrate Sub to be described later to a paired element. In the present specification, a +z direction may be expressed as “up” and a −z direction may be expressed as “down”, but these expressions are for convenience and do not specify a direction of gravity. In addition, in the present specification, “extending in the x direction” means, for example, that a dimension in the x direction is larger than a smallest dimension among dimensions in the x direction, the y direction, and the z direction. The same applies to extending in other directions. Further, in the present specification, “connecting” is not limited to direct connection, and includes connection via another object.

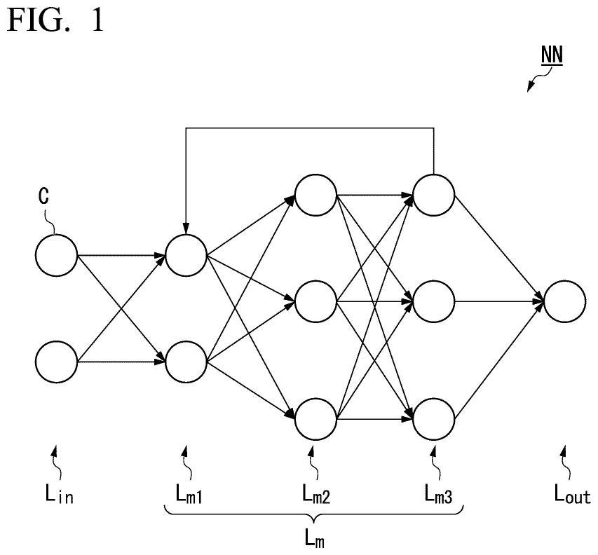

FIG. 1 is a schematic diagram of a neural network NN. The neural network NN includes an input layer Lᵢₙ, intermediate layers Lᵢₙ, and an output layer Lₒᵤₜ. In FIG. 1, an example in which three intermediate layers Lᵢₙ are included is presented, but the number of intermediate layers Lᵢₙ is not limited. Each of the input layer Lᵢₙ, the intermediate layers Lᵢₙ, and the output layer Lₒᵤₜ includes a plurality of chips C, and each chip C corresponds to a neuron in a brain. The input layer Lᵢₙ, the intermediate layers Lᵢₙ, and the output layer Lₒᵤₜ are connected by a transfer means. The transfer means corresponds to a synapse in the brain.

The neural network NN increases a rate of correct answers to a question through learning of the transfer means (synapses). The learning is finding knowledge that can be used in the future from information. The neural network NN operates while changing a weight of the transfer means, to perform learning. The transfer means performs a product calculation in which the input signal is weighted, and a sum calculation of adding results of the product calculation. In other words, the transfer means performs a product-sum calculation.

Each of a first magnetoresistance effect element 10 and a second magnetoresistance effect element 20 of a paired element 100 to be described later functions as a product calculation element. Further, a magnetic array 2 to be described later functions as a product-sum calculator.

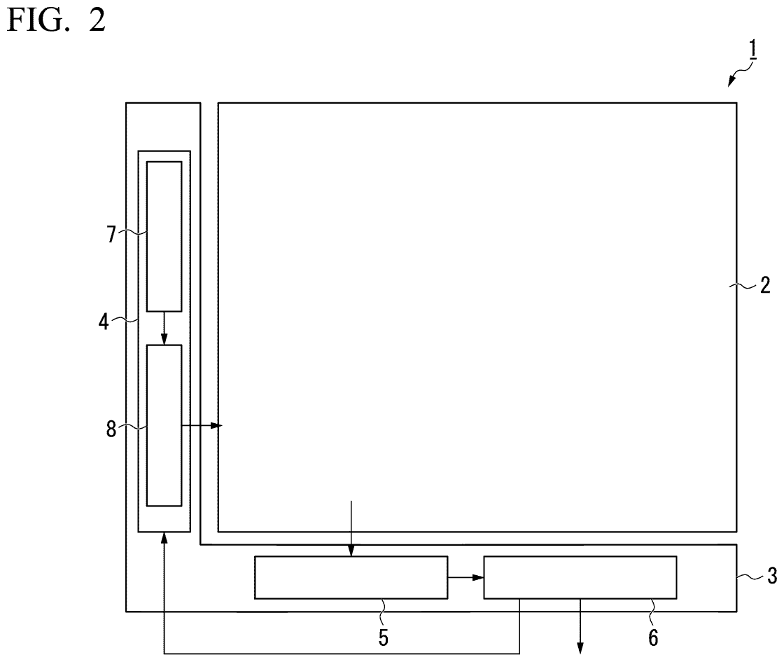

FIG. 2 is a block diagram of the neuromorphic device 1 according to the first embodiment. The neuromorphic device 1 includes the magnetic array 2 and a control device 3.

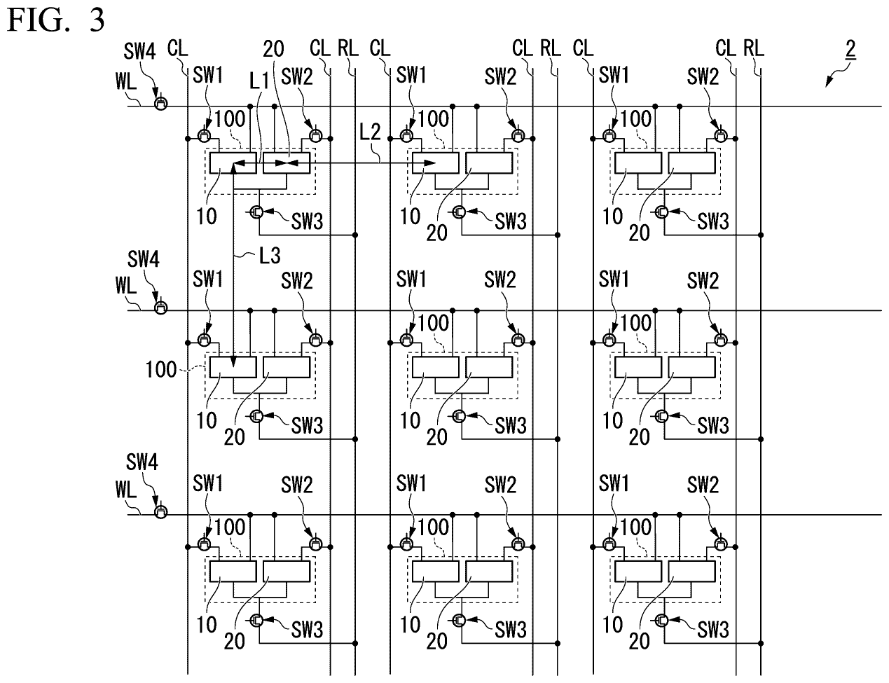

The magnetic array 2 has a plurality of paired elements 100 (see FIG. 3) integrated therein. The magnetic array 2 is a product-sum calculator that is responsible for the learning of the neuromorphic device. The control device 3 controls an operation of the paired elements 100 in the magnetic array 2. The control device 3 is located, for example, around the magnetic array 2 as illustrated in FIG. 2. The control device 3 may be disposed in a position overlapping with the magnetic array 2 in a z-direction.

The control device 3 includes, for example, a signal input unit 4, a calculation unit 5, and an output unit 6. The control device 3 controls each of the plurality of paired elements 100.

The signal input unit 4 includes a control unit 7 and a power supply 8. The control unit 7 includes, for example, a processor and a memory. The processor is, for example, a central processing unit (CPU). The processor controls, for example, an address of an element that applies a pulse, a potential of the element that applies a pulse, a magnitude of a pulse applied to the element (a voltage or pulse length), and the like. The memory stores the address of the element, a program that operates the processor, and the like.

The calculation unit 5 calculates a weight from the resistance of the element in the magnetic array 2 and the output current from the element. The calculation unit 5 includes, for example, a processor and performs calculations. The calculation unit 5 detects, for example, the output current from the element in the magnetic array 2, and applies a detection result to an activation function.

The output unit 6 is connected to the calculation unit 5. The output unit 6 outputs a calculation result of the calculation unit 5 to the outside. The output unit 6 includes, for example, an output capacitor, an amplifier, and a converter. Further, the output unit 6 may feed the calculation result back to the signal input unit 4. The calculation result is stored, for example, in a memory of the signal input unit 4.

FIG. 3 is a circuit diagram of the magnetic array 2 of the neuromorphic device according to the first embodiment. The magnetic array 2 includes a plurality of paired elements 100, a plurality of first lines WL, a plurality of second lines CL, a plurality of third lines RL, a plurality of first switching elements SW1, a plurality of second switching elements SW2, a plurality of third switching elements SW3, and a plurality of fourth switching elements SW4. The fourth switching element SW4 may belong to, for example, the signal input unit 4 of the control device 3.

Each of the paired elements 100 includes the first magnetoresistance effect element 10 and the second magnetoresistance effect element 20. A distance L1 between the first magnetoresistance effect element 10 and the second magnetoresistance effect element 20 belonging to the same paired element 100 is shorter than, for example, the distance L2 between the first magnetoresistance effect element 10 and the second magnetoresistance effect element 20 belonging to the other paired element 100. In addition, the distance L1 between the first magnetoresistance effect element 10 and the second magnetoresistance effect element 20 belonging to the same paired element 100 is shorter than, for example, a distance L3 between the first magnetoresistance effect element 10 and the first magnetoresistance effect element 10 belonging to different paired elements 100. These distances L1, L2, and L3 are the shortest distances between the elements. Here, although a case where the plurality of paired elements 100 are arranged in a plane has been illustrated, some of the plurality of paired elements 100 may be arranged three-dimensionally. In this case, any of these distances L1, L2, and L3 may be a distance in the z direction. When the distance LI between the first magnetoresistance effect element 10 and the second magnetoresistance effect element 20 belonging to the same paired element 100 is the shortest, thermal interference between different paired elements 100 can be reduced.

Each of the first lines WL is a write line, Each of the first lines WL electrically connects the signal input unit 4 to one or more of the paired elements 100. Each of the second lines CL is a common line that can be used both when a signal is written and when a signal is read. Each of the second lines CL is connected to, for example, the signal input unit 4 or the calculation unit 5. The second line CL may be provided in the plurality of paired elements 100 or may be provided across the plurality of paired elements 100. Each of the third lines RL is a read line. The third lines RL electrically connect, for example, the calculation unit 5 and one or more paired elements 100.

The first switching element SW1, the second switching element SW2, the third switching element SW3, and the fourth switching element SW4 are elements that control a flow of current. The first switching element SW1, the second switching element SW2, the third switching element SW3, and the fourth switching element SW4 are, for example, transistors, elements using a phase change of a crystal layer such as an ovonic threshold switch (OTS), elements using change in band structure such as a metal-insulator transition (MIT) switch, elements using a breakdown voltage such as a Zener diode and an avalanche diode, and elements of which conductivity changes with change in atomic position.

The first switching element SW1, the second switching element SW2, and the third switching element SW3 are connected to the respective paired element 100 one by one. The fourth switching element SW4 is disposed upstream of any one of the first line WL, the second line CL, and the third line RL.

The first switching element SW1 is, for example, between the first magnetoresistance effect element 10 and the second line CL. The second switching element SW2 is, for example, between the second magnetoresistance effect element 20 and the second line CL. The third switching element SW3 is, for example, between each paired element 100 and the third line RL. The first switching element SW1, the second switching element SW2, and the third switching element SW3 have a large influence on the integration of the magnetic array 2.

The fourth switching element SW4 is, for example, between the signal input unit 4 and each paired element 100. The fourth switching element SW4 is, for example, connected to the first line WL. The fourth switching element SW4 can be disposed on the outer side of the magnetic array 2, and has a small influence on the integration of the magnetic array 2.

The disposition of the switching elements is not limited to the example in FIG. 3. For example, the first switching element SW1 may be disposed between the first magnetoresistance effect element 10 and the first line WL, the second switching element SW2 may be disposed between the second magnetoresistance effect element 20 and the first line WL, and the fourth switching element SW4 may be disposed between the second line CL and the calculation unit 5. For example, the third switching element SW3 may be disposed upstream of the third line RL. Further, the number of switching elements connected to each paired element 100 may also be increased.

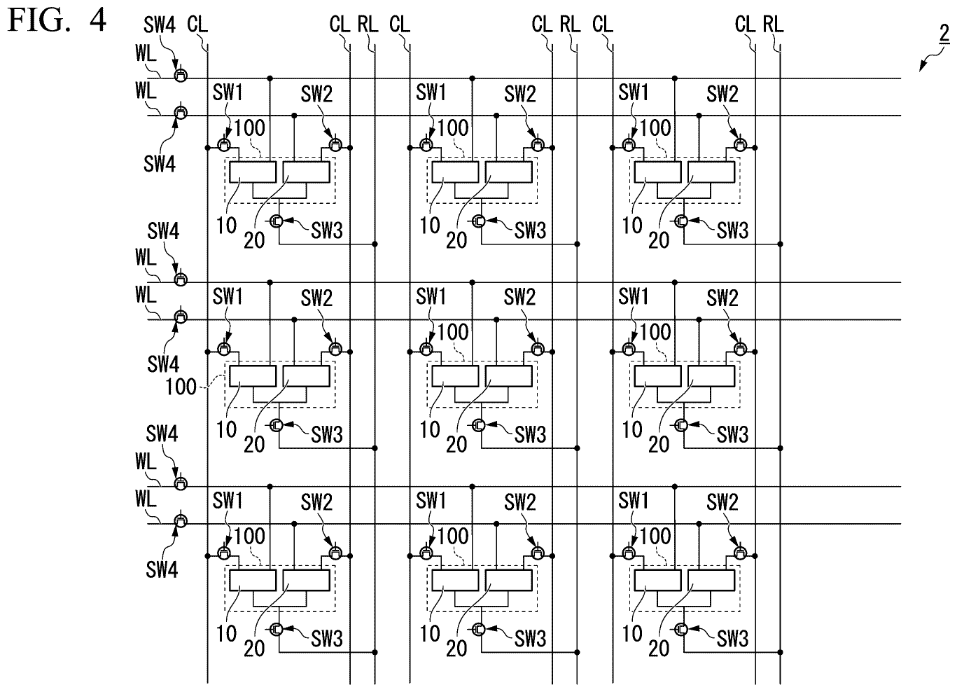

Further, the circuit diagram of the magnetic array 2 is not limited to this example. For example, FIG. 4 is a circuit diagram of another example of the magnetic array 2 of the neuromorphic device according to the first embodiment. In the circuit diagram illustrated in FIG. 4, the first magnetoresistance effect element 10 and the second magnetoresistance effect element 20 belonging to the same paired element 100 are connected to the different first lines WL.

FIG. 5 is a cross-sectional view of the vicinity of the paired element 100 of the magnetic array 2 according to the first embodiment. FIG. 5 illustrates a cross-section of one paired element 100 in FIG. 3 taken in an xz plane passing through a center in the y direction.

The first switching element SW1, the second switching element SW2, and the third switching element SW3 illustrated in FIG. 5 are transistors Tr. The transistor Tr has a gate electrode G, a gate insulating film GI, and a source S and a drain D formed on the substrate Sub. The source S and the drain D are defined by a direction in which a current flows, and are the same region. FIG. 5 shows only one example, and a positional relationship between the source S and the drain D may be reversed.

The substrate Sub is, for example, a semiconductor substrate. The fourth switching element SW4 is electrically connected to the first line WL and, for example, is at position shifted in the x direction from FIG. 5.

The transistor Tr, the first line WL, the second line CL, the third line RL, and the paired element 100 are located at different layers in the z direction. The different layers are connected by a via line V. The via line V includes a material having electrical conductivity: An insulating layer 90 is formed between the different layers in the z direction, except for the via line V.

The insulating layer 90 is an insulating layer that insulates between lines of a multilayer line and between elements. The paired element 100 and the transistor Tr are electrically isolated by the insulating layer 90, except for the via line V. The insulating layer 90 is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), or zirconium oxide (ZrOₓ).

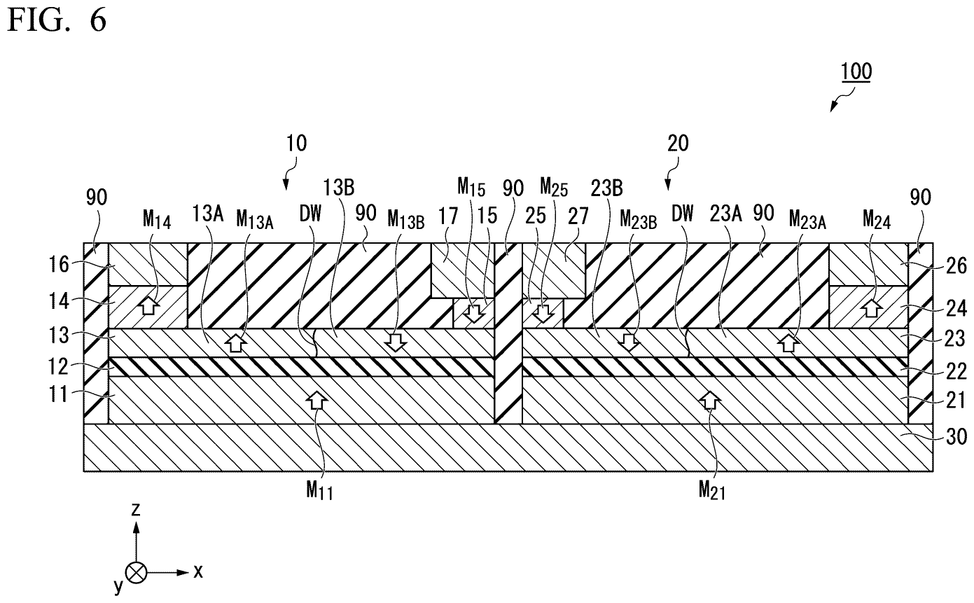

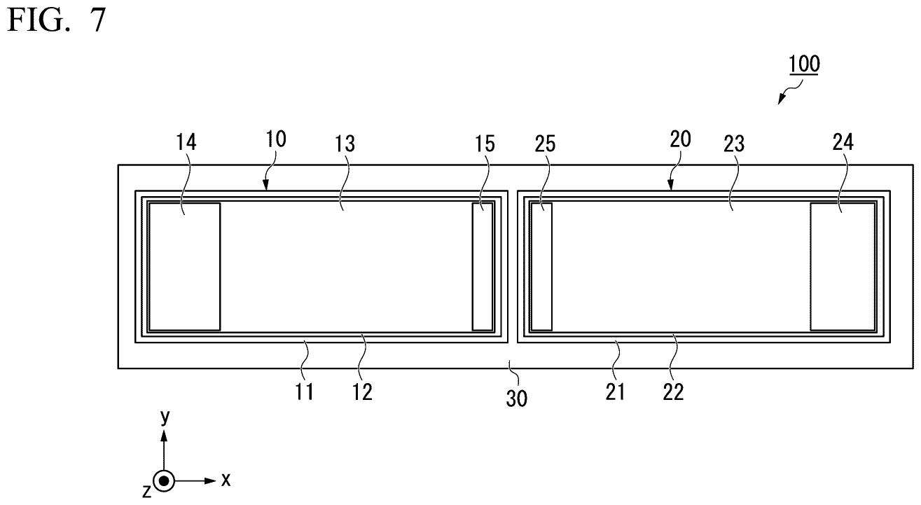

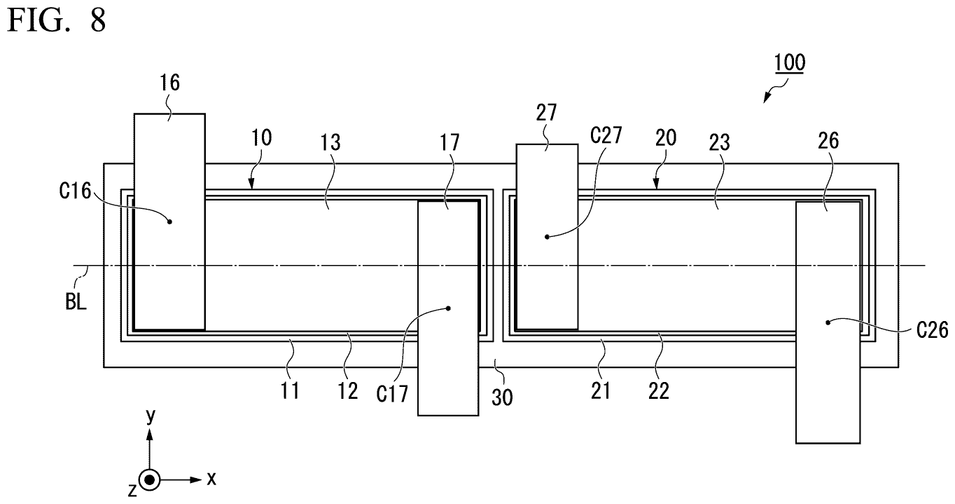

FIG. 6 is a cross-sectional view of the paired element 100 according to the first embodiment. FIG. 6 illustrates an xz cross-section passing through the center of the paired element 100 in the y direction. FIGS. 7 and 8 are plan views of the paired element 100 according to the first embodiment when viewed from the z direction. FIG. 7 is a plan view of the paired element 100 excluding the first electrode 16, the second electrode 17, the third electrode 26, and the fourth electrode 27.

Each of the paired elements 100 includes the first magnetoresistance effect element 10, the second magnetoresistance effect element 20, and a readout electrode 30. The first magnetoresistance effect element 10 and the second magnetoresistance effect element 20 belonging to the same paired element 100 are, for example, aligned in a longitudinal direction (x direction) of the first magnetoresistance effect element 10.

The readout electrode 30 is shared by the first magnetoresistance effect element 10 and the second magnetoresistance effect element 20. Since the first magnetoresistance effect element 10 and the second magnetoresistance effect element 20 share the readout electrode 30, the first magnetoresistance effect element 10 and the second magnetoresistance effect element 20 are thermally connected, and a temperature variation between the first magnetoresistance effect element 10 and the second magnetoresistance effect element 20 is reduced.

When viewed from the z direction, for example, the readout electrode 30 includes the first magnetoresistance effect element 10 and the second magnetoresistance effect element 20. When a heat capacity of the readout electrode 30 is large, heat exhaustion of the first magnetoresistance effect element 10 and the second magnetoresistance effect element 20 is improved. Further, when the readout electrode 30 includes the first magnetoresistance effect element 10 and the second magnetoresistance effect element 20, heat bias inside the paired element 100 can be alleviated.

The first magnetoresistance effect element 10 includes a first reference layer 11, a first non-magnetic layer 12, a first magnetic recording layer 13, a first magnetization fixing layer 14, a second magnetization fixing layer 15, a first electrode 16, and a second electrode 17.

The second magnetoresistance effect element 20 includes a second reference layer 21, a second non-magnetic layer 22, a second magnetic recording layer 23, a third magnetization fixing layer 24, a fourth magnetization fixing layer 25, a third electrode 26, and a fourth electrode 27.

The readout electrode 30 is connected across the first reference layer 11 and the second reference layer 21. The readout electrode 30 includes the first reference layer 11 and the second reference layer 21, for example, when viewed from the z direction.

Each of the first reference layer 11 and the second reference layer 21 includes a ferromagnetic material. Magnetization M₁₁ of the first reference layer 11 is more difficult to be reversed than magnetizations M_{13A} and M_{13B} of the first magnetic recording layer 13. Magnetization M₂₁ of the second reference layer 21 is more difficult to be reverse than magnetizations M_{23A} and M_{23B} of the second magnetic recording layer 23.

The first reference layer 11 is closer to the substrate Sub than the first magnetic recording layer 13. The second reference layer 21 is closer to the substrate Sub than the second magnetic recording layer 23. Such an element is called a bottom pin structure.

As illustrated in FIG. 7, the first reference layer 11 includes the first magnetic recording layer 13 when viewed from the z direction. Further, the second reference layer 21 includes the second magnetic recording layer 23 when viewed from the z direction. When an area of the reference layer is large, a heat capacity of the reference layer increases, and heat exhaustion efficiency of the magnetic recording layer increases.

The first reference layer 11 includes, for example, a material allowing a coherent tunnel effect to be easily obtained with the first magnetic recording layer 13. The second reference layer 21 includes, for example, a material allowing a coherent tunnel effect to be easily obtained with the second magnetic recording layer 23. Each of the first reference layer 11 and the second reference layer 21 includes, for example, a metal selected from a group consisting of Cr, Mn, Co, Fe, a Ni, an alloy including one or more of these metals, and an alloy including these metals and at least one of elements B, C, and N. The first reference layer 11 and the second reference layer 21 are, for example, Co—Fe, Co—Fe—B, and Ni—Fe.

Each of the first reference layer 11 and the second reference layer 21 may be, for example, a Heusler alloy. The Heusler alloy is half-metallic and has high spin polarizability. The Heusler alloy is an intermetallic compound with a chemical composition of XYZ or X₂YZ, where X is a transition metal element or a noble metal element of Co, Fe, Ni, or Cu group on a periodic table, Y is a transition metal element of a Mn, V, Cr, or Ti group or an element type of X, and Z is a typical element of a group III to V. Examples of the Heusler alloy may include Co₂FeSi, Co₂FeGe, Co₂FeGa, Co₂MnSi, Co₂Mn₁₋ₐFeₐAl_{b}Si_{1-b}, and Co₂FeGe₁₋ₑGa_{c}.

Each of the first reference layer 11 and the second reference layer 21 may have a synthetic antiferromagnetic structure (SAF structure). The synthetic antiferromagnetic structure is made of two magnetic layers sandwiching a non-magnetic layer. For example, each of the first reference layer 11 and the second reference layer 21 may be a ferromagnetic layer, a spacer layer, and a laminate of the ferromagnetic layer. The two ferromagnetic layers constituting the SAF structure are antiferromagnetically coupled, so that a coercive force of the first reference layer 11 and the second reference layer 21 is greater than that in the case of a non-SAF structure. The magnetic layer constituting the SAF structure includes, for example, a ferromagnetic material, and may include an antiferromagnetic material such as IrMn or PtMn. The spacer layer includes, for example, at least one selected from a group consisting of Ru, Ir, and Rh.

The first non-magnetic layer 12 is between the first reference layer 11 and the first magnetic recording layer 13. The first non-magnetic layer 12 is on the first reference layer 11. The second non-magnetic layer 22 is between the second reference layer 21 and the second magnetic recording layer 23. The second non-magnetic layer 22 is on the second reference layer 21.

Each of the first non-magnetic layer 12 and the second non-magnetic layer 22 is made of, for example, a non-magnetic insulator, semiconductor, or metal. The non-magnetic insulator is, for example, Al₂O₃, SiO₂, MgO, MgAl₂O₄, or a material in which some of Al, Si and Mg thereof are replaced with Zn, Be, or the like. These materials have a large band gap and an excellent insulating property. When the first non-magnetic layer 12 and the second non-magnetic layer 22 are made of a non-magnetic insulator, each of the first non-magnetic layer 12 and the second non-magnetic layer 22 is a tunnel barrier layer. The non-magnetic metal is, for example, Cu, Au, Ag, or the like. The non-magnetic semiconductor is, for example, Si, Ge, CuInSe₂, CuGaSe₂, Cu(In, Ga)Se₂, or the like.

A thickness of each of the first non-magnetic layer 12 and the second non-magnetic layer 22 is, for example, 20 Å or more, and may be 25 Å or more. When the thickness of the first non-magnetic layer 12 is large, a resistance area product (RA) of the first magnetoresistance effect element 10 increases. When the thickness of the second non-magnetic layer 22 is large, a resistance area product (RA) of the second magnetoresistance effect element 20 increases. The resistance area product (RA) is preferably 1×10⁴ Ωμm² or more, and more preferably 5×10⁴ Ωμm² or more. The resistance area product (RA) is expressed as a product of an element resistance and an element cross-sectional area. The element cross section is a cross section taken along an xy plane passing through the first non-magnetic layer 12 or the second non-magnetic layer 22.

The first magnetic recording layer 13 is on the first non-magnetic layer 12. The second magnetic recording layer 23 is on the second non-magnetic layer 22.

The first magnetic recording layer 13 and the second magnetic recording layer 23 each extend in the x direction. The first magnetic recording layer 13 and the second magnetic recording layer 23 each extend in the same direction as the first reference layer 11 and the second reference layer 21.

Each of the first magnetic recording layer 13 and the second magnetic recording layer 23 has a domain wall DW therein. The domain wall DW is a boundary between different domains. The domain wall DW moves in the x direction inside each of the first magnetic recording layer 13 and the second magnetic recording layer 23. The magnetic recording layer is also called an analog layer or a domain wall displacement layer.

The first magnetic recording layer 13 has a first domain 13A and a second domain 13B. The domain wall DW is present at a boundary between the first domain 13A and the second domain 13B. Magnetization M_{13A} of the first domain 13A is oriented in the same direction as magnetization M₁₄ of the first magnetization fixing layer 14, for example. Magnetization M_{13B} of the second domain 13B is oriented in the same direction as magnetization M₁₅ of the second magnetization fixing layer 15, for example.

When a volume ratio between the first domain 13A and the second domain 13B changes, the domain wall DW moves, The domain wall DW moves by applying a write current (for example, a current pulse) in the x direction of the first magnetic recording layer 13, by applying an external magnetic field to the first magnetic recording layer 13, or the like.

The second magnetic recording layer 23 includes a third domain 23A and a fourth domain 23B. The domain wall DW is present at a boundary between the third domain 23A and the fourth domain 23B. Magnetization M_{23A} of the third domain 23A is oriented in the same direction as magnetization M₂₄ of the third magnetization fixing layer 24, for example. The magnetization M_{23B} of the fourth domain 23B is oriented in the same direction as magnetization M₂₅ of the fourth magnetization fixing layer 25, for example.

When a volume ratio between the third domain 23A and the fourth domain 23B changes, the domain wall DW moves. The domain wall DW moves by applying a write current (for example, a current pulse) in the x direction of the second magnetic recording layer 23, by applying an external magnetic field to the second magnetic recording layer 23, or the like.

The first magnetic recording layer 13 and the second magnetic recording layer 23 are each made of a magnetic material. For the first magnetic recording layer 13 and the second magnetic recording layer 23, the same material as those of the first reference layer 11 and the second reference layer 21 may be used.

Each of the first magnetic recording layer 13 and the second magnetic recording layer 23 may be a ferromagnetic material, a ferrimagnetic material, or a combination of these with an antiferromagnetic material of which a magnetic state can be changed due to a current. Each of the first magnetic recording layer 13 and the second magnetic recording layer 23 preferably has at least one element selected from a group consisting of Co, Ni, Fe, Pt, Pd, Gd, Tb, Mn, Ge, and Ga,

Examples of materials used for the first magnetic recording layer 13 and the second magnetic recording layer 23 may include a laminated film of Co and Ni, a laminated film of Co and Pt, a laminated film of Co and Pd, a MnGa-based material, a GdCo-based material, and a TbCo-based material. Ferrimagnetic materials such as the MnGa-based material, the GdCo-based material, and the TbCo-based material have low saturation magnetization, and a threshold current required to move the domain wall DW becomes small. Further, the laminated film of Co and Ni, the laminated film of Co and Pt, and the laminated film of Co and Pd have high coercive force, and a movement speed of the domain wall DW is low. Examples of the antiferromagnetic material include Mn₃X (X is Sn, Ge, Ga, Pt, Ir, or the like), CuMnAs, and Mn₂Au.

The first magnetization fixing layer 14 comes into direct or indirect contact with a part of the first magnetic recording layer 13. The indirect contact means that another layer is sandwiched between the first magnetization fixing layer 14 and the first magnetic recording layer 13. The first magnetization fixing layer 14 comes into contact, for example, with a first end of the first magnetic recording layer 13. The first magnetization fixing layer 14 is between the first magnetic recording layer 13 and the first electrode 16. The first magnetization fixing layer 14 fixes the magnetization M_{13A} of the first magnetic recording layer 13 located near the first magnetization fixing layer 14.

The second magnetization fixing layer 15 comes into direct or indirect contact with a part of the first magnetic recording layer 13. The indirect contact means that another layer is sandwiched between the second magnetization fixing layer 15 and the first magnetic recording layer 13. The second magnetization fixing layer 15 comes into contact with, for example, a second end of the first magnetic recording layer 13. The second magnetization fixing layer 15 is between the first magnetic recording layer 13 and the second electrode 17. The second magnetization fixing layer 15 fixes the magnetization M_{13B} of the first magnetic recording layer 13 located near the second magnetization fixing layer 15. The orientation direction of the magnetization M_{13B} of the second magnetization fixing layer 15 is opposite to the orientation direction of the magnetization M₁₄ of the first magnetization fixing layer 14.

The third magnetization fixing layer 24 comes into direct or indirect contact with a part of the second magnetic recording layer 23. The indirect contact means that another layer is sandwiched between the third magnetization fixing layer 24 and the second magnetic recording layer 23. The third magnetization fixing layer 24 comes into contact, for example, with a first end of the second magnetic recording layer 23. The third magnetization fixing layer 24 is between the second magnetic recording layer 23 and the third electrode 26. The third magnetization fixing layer 24 fixes the magnetization M_{23A} of the second magnetic recording layer 23 located near the third magnetization fixing layer 24. The orientation direction of the magnetization M₂₄ of the third magnetization fixing layer 24 is the same as the orientation direction of the magnetization M₁₄ of the first magnetization fixing layer 14.

The fourth magnetization fixing layer 25 comes into direct or indirect contact with a part of the second magnetic recording layer 23. The indirect contact means that another layer is sandwiched between the fourth magnetization fixing layer 25 and the second magnetic recording layer 23. The fourth magnetization fixing layer 25 comes into contact with, for example, a second end of the second magnetic recording layer 23. The fourth magnetization fixing layer 25 is between the second magnetic recording layer 23 and the fourth electrode 27. The fourth magnetization fixing layer 25 fixes magnetization M_{23B} of the second magnetic recording layer 23 located near the fourth magnetization fixing layer 25. The orientation direction of the magnetization M₂₅ of the fourth magnetization fixing layer 25 is opposite to the orientation direction of the magnetization M₁₄ of the first magnetization fixing layer 14 and the magnetization M₂₄ of the third magnetization fixing layer 24.

As illustrated in FIG. 6, for example, a height in the z direction of the first magnetization fixing layer 14 and a height in the z direction of the second magnetization fixing layer 15 may be different. Further, for example, a height in the z direction of the third magnetization fixing layer 24 and a height in the z direction of the fourth magnetization fixing layer 25 may be different.

As illustrated in FIG. 7, for example, an area of the first magnetization fixing layer 14 and an area of the second magnetization fixing layer 15 may be different when viewed from the z direction. For example, the area of the first magnetization fixing layer 14 is larger than the area of the second magnetization fixing layer 15 when viewed from the z direction. Further, for example, an area of the third magnetization fixing layer 24 and an area of the fourth magnetization fixing layer 25 may be different when viewed from the z direction. For example, the area of the third magnetization fixing layer 24 is larger than the area of the fourth magnetization fixing layer 25 when viewed from the z direction.

When heights or areas of the respective magnetization fixing layers are different and volumes of the magnetization fixing layers are different, coercive forces of the magnetization fixing layers are different. It becomes easier to set the orientation direction of the magnetization by changing the coercive forces of the magnetization fixing layers.

Each of the first magnetization fixing layer 14, the second magnetization fixing layer 15, the third magnetization fixing layer 24, and the fourth magnetization fixing layer 25 is, for example, a ferromagnetic material. For example, the same materials as those of the first reference layer 11, the second reference layer 21, the first magnetic recording layer 13, and the second magnetic recording layer 23 can be applied to the layers. Further, the layers are not limited to ferromagnetic materials. For example, when the first magnetization fixing layer 14 is not a ferromagnetic material, a current density of the current flowing through the first magnetic recording layer 13 changes suddenly in a region overlapping with the first magnetization fixing layer 14, thereby restricting the movement of the domain wall DW.

Further, any of the first magnetization fixing layer 14, the second magnetization fixing layer 15, the third magnetization fixing layer 24, and the fourth magnetization fixing layer 25 may have the above-described SAF structure. For example, a film thickness of the ferromagnetic layer constituting the SAF structure may be different between the first magnetization fixing layer 14 and the second magnetization fixing layer 15. Further, for example, the film thickness of the ferromagnetic layer constituting the SAF structure may be different between the third magnetization fixing layer 24 and the fourth magnetization fixing layer 25. When the film thicknesses of the ferromagnetic layers are different, coercive forces of respective magnetization fixing layers are different, making it easier to set a magnetization orientation direction.

The first electrode 16 is electrically connected to the first magnetic recording layer 13. The first electrode 16 is electrically connected, for example, to the first end of the first magnetic recording layer 13. The first electrode 16 is, for example, on the first magnetization fixing layer 14. The first electrode 16 is electrically connected, for example, to the first switching element SW1 and the second line CL. A current flows through the first electrode 16 both when a signal is written and when a signal is read.

The second electrode 17 is spaced apart from the first electrode 16 and electrically connected to the first magnetic recording layer 13. The second electrode 17 is electrically connected, for example, to the second end of the first magnetic recording layer 13. The second electrode 17 is, for example, on the second magnetization fixing layer 15. The second electrode 17 is electrically connected to, for example, the first line WL. A current flows through the second electrode 17 when a signal is written.

The third electrode 26 is electrically connected to the second magnetic recording layer 23. The third electrode 26 is electrically connected to, for example, the first end of the second magnetic recording layer 23. The third electrode 26 is, for example, on the third magnetization fixing layer 24. The third electrode 26 is electrically connected to, for example, the second switching element SW2 and the second line CL. A current flows through the third electrode 26 both when a signal is written and when a signal is read.

The fourth electrode 27 is spaced apart from the third electrode 26 and electrically connected to the second magnetic recording layer 23. The fourth electrode 27 is electrically connected to, for example, the second end of the second magnetic recording layer 23. The fourth electrode 27 is, for example, on the fourth magnetization fixing layer 25. The fourth electrode 27 is electrically connected to, for example, the first line WL. A current flows through the fourth electrode 27 when a signal is written.

A distance between the first electrode 16 and the third electrode 26 is, for example, longer than that between the second electrode 17 and the fourth electrode 27. The heat generation of the entire pair element 100 can be suppressed because the distance between the first electrode 16 and the third electrode 26, where current flows frequently because current flows both when a signal is written and when a signal is read, is longer.

Further, as illustrated in FIG. 8, shapes of the first electrode 16, the second electrode 17, the third electrode 26, and the fourth electrode 27 may be different from the shapes of the first magnetization fixing layer 14, the second magnetization fixing layer 15, the third magnetization fixing layer 24, and the fourth magnetization fixing layer 25, when viewed from the z direction. For example, a size of each electrode when viewed from the z direction may be larger than a size of the magnetization fixing layer connected to each electrode.

Further, when viewed from the z direction, at least two of geometric centers C16, C17, C26, and C27 of the first electrode 16, the second electrode 17, the third electrode 26, and the fourth electrode 27 belonging to the same paired element 100 are at positions sandwiching the readout electrode 30, for example. For example, the geometric center C16 of the first electrode 16 and the geometric center C17 of the second electrode 17 sandwich a reference line BL passing through a center of the readout electrode 30 in the y direction. Further, for example, the geometric center C26 of the third electrode 26 and the geometric center C27 of the fourth electrode 27 sandwich the reference line BL passing through the center of the readout electrode 30 in the y direction. At least one of the geometric centers of the electrodes, which is one of heat exhaustion paths, is disposed on the opposite side of the reference line BL, so that the heat bias inside the paired element 100 can be alleviated.

Each of the first electrode 16, the second electrode 17, the third electrode 26, and the fourth electrode 27 includes a conductor. Each of the first electrode 16, the second electrode 17, the third electrode 26, and the fourth electrode 27 is, for example, Cu, Al, Au, Ta, or Ru.

The magnetization direction of each layer of the paired element 100 can be confirmed, for example, by measuring a magnetization curve. The magnetization curve can be measured, for example, using Magneto Optical Kerr Effect (MOKE). The measurement using the MOKE is a measurement method that is performed by causing linearly polarized light to be incident on a measurement target object and using a magneto-optical effect (magnetic Kerr effect) in which, for example, rotation of a polarization direction occurs.

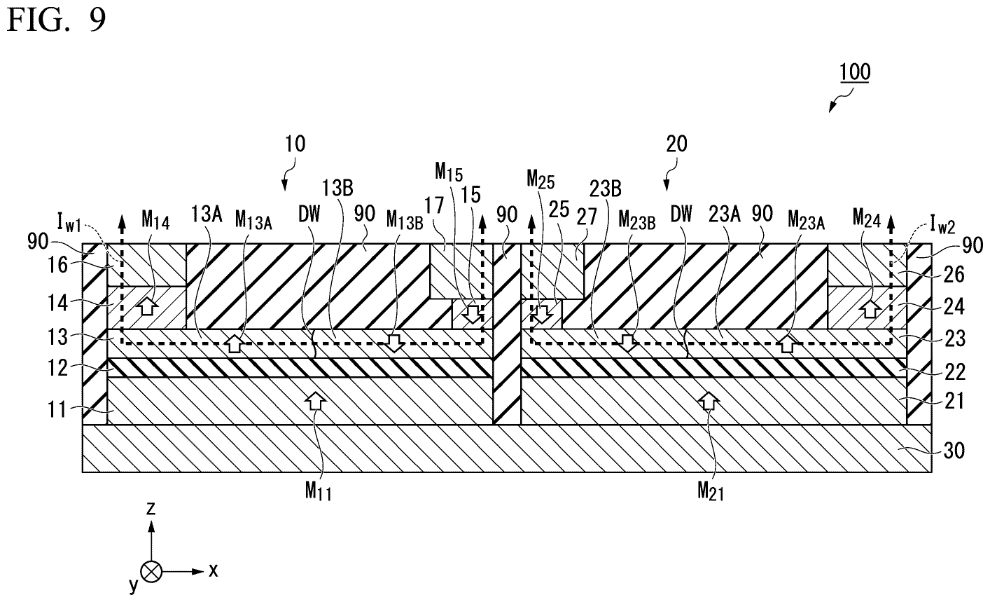

Next, an operation of writing a signal to the paired element 100 will be described. FIG. 9 is a diagram illustrating a write operation of the paired element 100 according to the first embodiment. The paired element 100 performs the write operation separately on each of the first magnetoresistance effect element 10 and the second magnetoresistance effect element 20.

When a signal is written to the first magnetoresistance effect element 10, a predetermined first switching element SW1 and a predetermined fourth switching element SW4 are turned ON, and the other switching elements are turned OFF. The control unit 7 controls which first switching element SW1 and fourth switching element SW4 are turned ON. The position of the domain wall DW changes when a write current I_{W1} is applied to the first magnetic recording layer 13. The control unit 7 can control a direction of a movement of the domain wall DW by controlling a potential of the first electrode 16 and the second electrode 17. When the position of the domain wall DW of the first magnetic recording layer 13 changes, a resistance value in the stacking direction of the first magnetoresistance effect element 10 changes. The resistance value or conductance in the stacking direction of the first magnetoresistance effect element 10 is the written signal, and corresponds to, for example, a positive weight.

When a signal is written to the second magnetoresistance effect element 20, a predetermined second switching element SW2 and a predetermined fourth switching element SW4 are turned ON, and the other switching elements are turned OFF. The control unit 7 controls which second switching element SW2 and fourth switching element SW4 are turned ON. The position of the domain wall DW changes when a write current I_{W2} is applied to the second magnetic recording layer 23. The control unit 7 can control a direction of a movement of the domain wall DW by controlling a potential of the third electrode 26 and the fourth electrode 27. When the position of the domain wall DW of the second magnetic recording layer 23 changes, a resistance value in the stacking direction of the second magnetoresistance effect element 20 changes. The resistance value of conductance in the stacking direction of the second magnetoresistance effect element 20 is a written signal and corresponds to, for example, a negative weight.

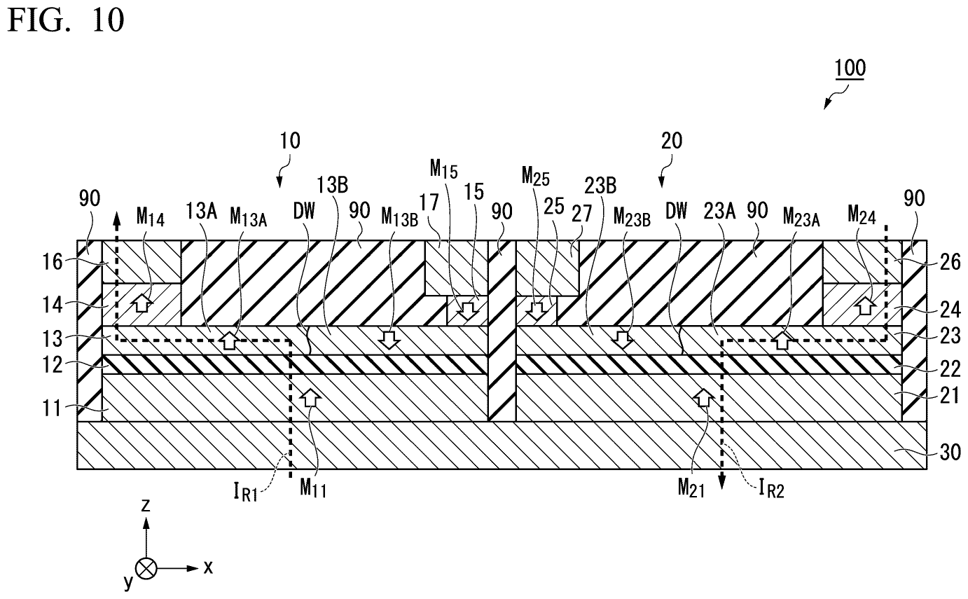

Next, an operation of reading a signal from the paired element 100 will be described. FIG. 10 is a diagram illustrating an operation of reading from the paired element 100 according to the first embodiment.

When a signal is read from the predetermined paired element 100, the predetermined first switching element SW1, the predetermined second switching element SW2, and the predetermined third switching element SW3 are turned ON, and the other switching elements are turned OFF.

In this case, the control device 3 causes a first read current I_{R1} and a second read current I_{R2} to flow through a specific paired element 100 from which a signal is to be read. The first read current I_{R1} flows through the inside of the first magnetoresistance effect element 10. The second read current I_{R2} flows through the inside of the second magnetoresistance effect element 20. When the first read current I_{R1} flows from the first reference layer 11 to the first magnetic recording layer 13, the second read current I_{R2} flows from the second magnetic recording layer 23 to the second reference layer 21. On the other hand, when the first read current I_{R1} flows from the first magnetic recording layer 13 to the first reference layer 11, the second read current I_{R2} flows from the second reference layer 21 to the second magnetic recording layer 23.

For example, the control device 3 reverses a direction of the read current I_{R1} flowing through the inside of the first magnetoresistance effect element 10 and a direction of the read current I_{R2} flowing through the inside of the second magnetoresistance effect element 20. For example, the control device 3 reverses a direction in which the first read current I_{R1} passes through the first non-magnetic layer 12 in the z direction (the +z direction in FIG. 10) and a direction in which the second read current I_{R2} passes through the second non-magnetic layer 22 in the z direction (the −z direction in FIG. 10).

For example, the first read current I_{R1} flows from the readout electrode 30 to the first electrode 16, and the second read current I_{R2} flows from the third electrode 26 to the readout electrode 30. Alternatively, the first read current I_{R1} may flow from the first electrode 16 to the readout electrode 30, and the second read current I_{R2} may flow from the readout electrode 30 to the third electrode 26. Directions in which the first read current I_{R1} and the second read current I_{R2} flow can be controlled by the control device 3 setting potentials of the first electrode 16, the third electrode 26, and the readout electrode 30, and a read current can be regarded as flowing when there is a potential difference between the electrodes.

It is possible to easily express the positive weight and the negative weight in the neural network by reversing the direction in which the read current flows, that is, causing the read current to flow from the reference layer to the magnetic recording layer or from the magnetic recording layer to the reference layer for the first read current I_{R1} and the second read current I_{R2}. Further, when the direction in which the read current flows is reversed, that is, when the read current flows from the reference layer to the magnetic recording layer or from the magnetic recording layer to the reference layer for the first read current I_{R1} and the second read current I_{R2}, directions of the transient components generated in the first magnetoresistance effect element 10 and the second magnetoresistance effect element 20 are also reversed immediately after the current is applied and immediately after the current application is stopped. Unexpected operations can be prevented by canceling out the transient components, which are error factors in the read operation, between the first magnetoresistance effect element 10 and the second magnetoresistance effect element 20.

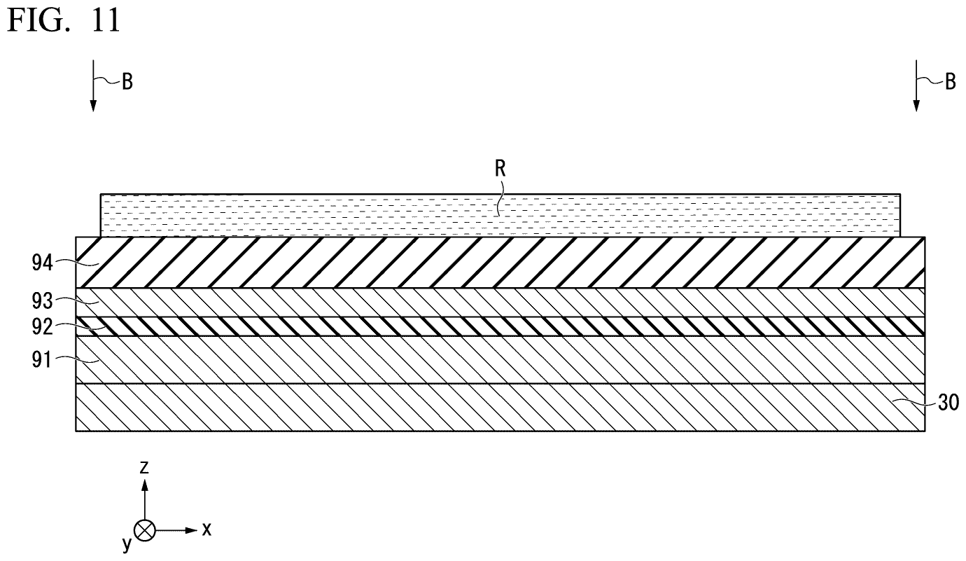

Next, a method of manufacturing the paired element 100 according to the first embodiment will be described. FIGS. 11 to 15 are diagrams showing an example of the method of manufacturing the paired element 100 according to the first embodiment.

The paired element 100 is formed by a lamination process for each layer, a processing process of processing a part of each layer into a predetermined shape, and a magnetic field application process of orienting magnetization in a predetermined direction.

As illustrated in FIG. 11, a ferromagnetic layer 91, a non-magnetic layer 92, a ferromagnetic layer 93, and a ferromagnetic layer 94 are formed in this order on the readout electrode 30. The layers may be formed by using a sputtering method, a chemical vapor deposition (CVD) method, an electron beam deposition (EB deposition method), an atomic laser deposition method, or the like.

Next, a resist R is formed on a part of the ferromagnetic layer 94, and an ion beam B is radiated through the resist R. The ion beam B etches the ferromagnetic layer 91, the non-magnetic layer 92, the ferromagnetic layer 93, and a part of the ferromagnetic layer 94 not protected by the resist R.

An outer shape connecting the first magnetic recording layer 13 and the second magnetic recording layer 23 is formed through processing using the ion beam B, and fine line widths of the first magnetic recording layer 13 and the second magnetic recording layer 23 are determined. A variation in the fine line width between the first magnetic recording layer 13 and the second magnetic recording layer 23 can be reduced by simultaneously processing the fine line widths of the first magnetic recording layer 13 and the second magnetic recording layer 23.

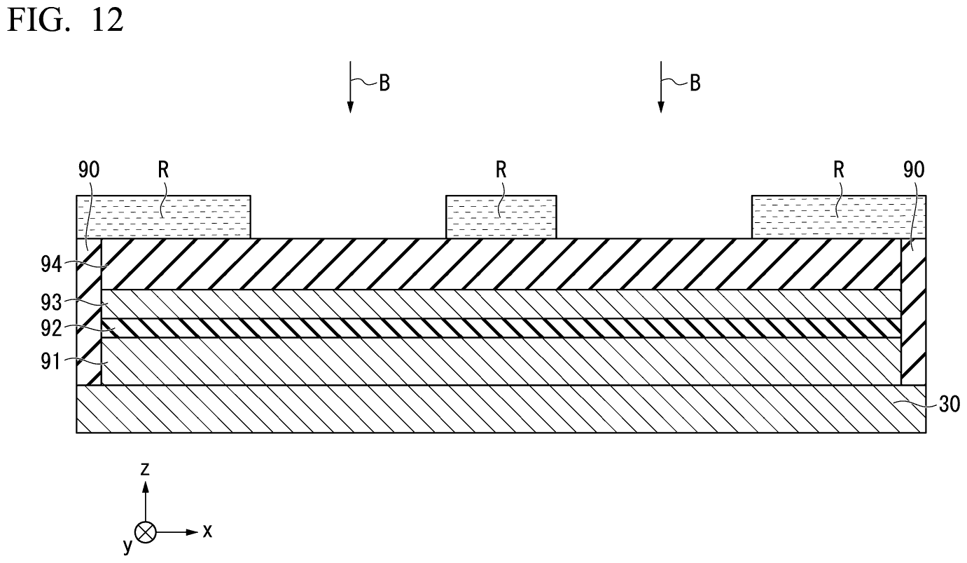

Then, the resist is removed, and the processed ferromagnetic layer 91, non-magnetic layer 92, ferromagnetic layer 93, and ferromagnetic layer 94 are filled with the insulating layer 90, as illustrated in FIG. 12. The resist R is formed again on a part of the ferromagnetic layer 94. The ion beam B is radiated through the resist R. The ion beam B etches a part of the ferromagnetic layer 94 that is not protected by the resist R.

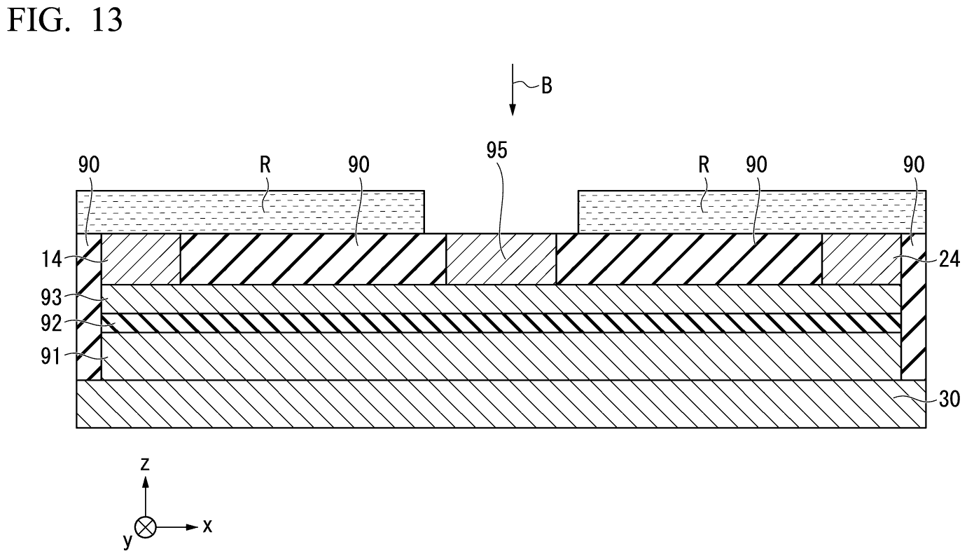

As illustrated in FIG. 13, the first magnetization fixing layer 14, the third magnetization fixing layer 24, and the ferromagnetic layer 95 are formed through processing with the ion beam B. The ferromagnetic layer 95 is a part that becomes the second magnetization fixing layer 15 and the fourth magnetization fixing layer 25 in subsequent processing. Next, a part removed by processing is refilled with the insulating layer 90, and the resist R is formed so that an upper surface of the ferromagnetic layer 95 is exposed. A thickness of the ferromagnetic layer 95 is reduced through radiation with the ion beam B.

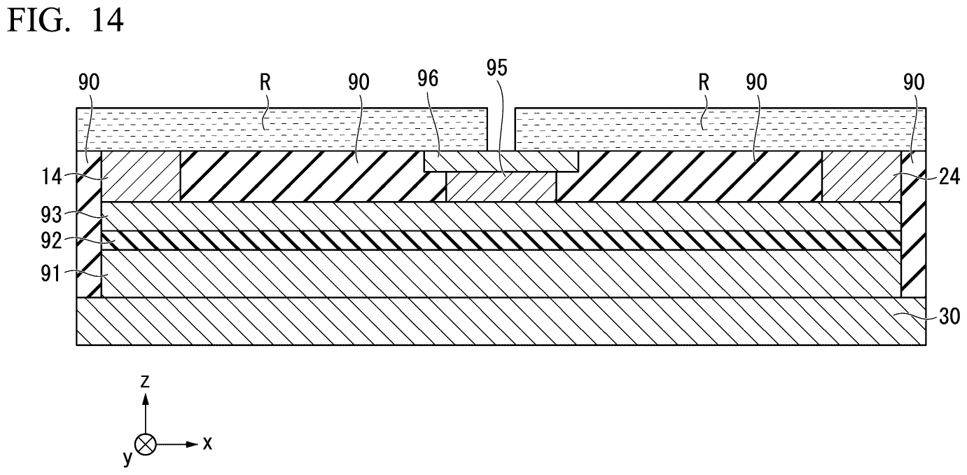

Next, a part removed by processing is filled with a conductor 96, as illustrated in FIG. 14. The conductor 96 is a part that becomes a part of the second electrode 17 and the fourth electrode 27 in subsequent processing. Next, the resist R is formed so that a part of an upper surface of the conductor 96 is exposed. The ion beam B is radiated through the resist R. The ion beam B separates the first magnetoresistance effect element 10 and the second magnetoresistance effect element 20.

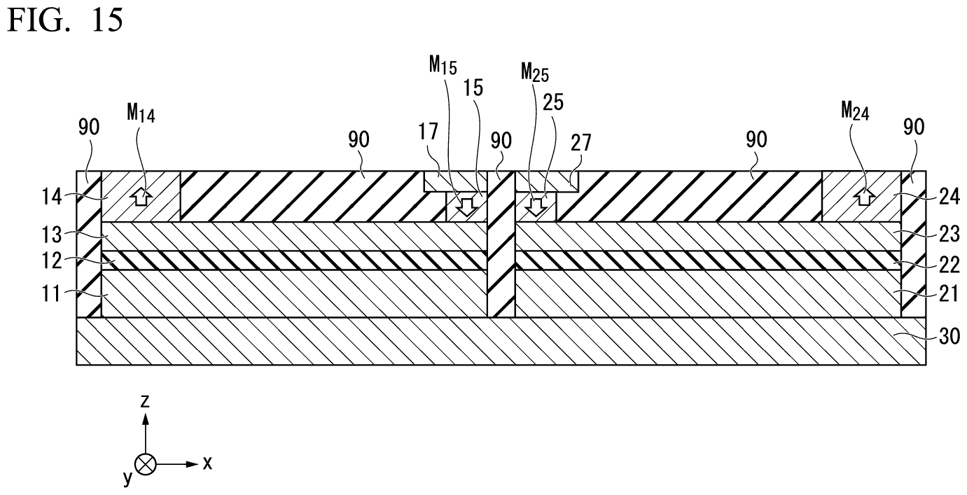

Next, a region between the first magnetoresistance effect element 10 and the second magnetoresistance effect element 20 is filled with an insulating layer 90, as illustrated in FIG. 15. The ferromagnetic layer 95 becomes the second magnetization fixing layer 15 and the fourth magnetization fixing layer 25. The conductor 96 becomes a part of the second electrode 17 and the fourth electrode 27. A conductive layer is formed on upper surfaces thereof and unnecessary parts are removed so that the first electrode 16 and the third electrode 26 are formed and the second electrode 17 and the fourth electrode 27 are stacked.

Next, an external magnetic field is applied in one direction (for example, the +z direction). When an external magnetic field is applied, the magnetizations M₁₄, M₁₅, M₂₄, and M₂₅ of the first magnetization fixing layer 14, the second magnetization fixing layer 15, the third magnetization fixing layer 24, and the fourth magnetization fixing layer 25 are all oriented in the same direction (for example, the +z direction).

Next, the external magnetic field is applied in an opposite direction (for example, the −z direction) to a direction in which the external magnetic field has been previously applied. For the external magnetic field, a magnetic field having an intensity with which one of the magnetization M₁₄ of the first magnetization fixing layer 14 and the magnetization M₁₅ of the second magnetization fixing layer 15 is reversed and the other is not reversed, and an intensity with which one of the magnetization M₂₄ of the third magnetization fixing layer 24 and the magnetization M₂₅ of the fourth magnetization fixing layer 25 is reversed and the other is not reversed is applied. A difference in coercivity between the first magnetization fixing layer 14 and the second magnetization fixing layer 15, and a difference in coercivity between the third magnetization fixing layer 24 and the fourth magnetization fixing layer 25 are caused by, for example, a difference in volume thereof. The external magnetic field is applied in this manner so that the magnetization is oriented in a predetermined direction, and the paired element 100 is obtained.

In the paired element 100 according to the first embodiment, the first magnetoresistance effect element 10 and the second magnetoresistance effect element 20 share the readout electrode 30. As a result, thermal histories of the first magnetoresistance effect element 10 and the second magnetoresistance effect element 20 are brought closer to each other, and a separate variation in a maximum resistance value and a minimum resistance value of the first magnetoresistance effect element 10 and a maximum resistance value and a minimum resistance value of the second magnetoresistance effect element 20 with temperature is curbed.

Further, with the neuromorphic device 1 according to the first embodiment, it is possible to express both the positive weight and the negative weight by setting the first magnetoresistance effect element 10 as a memristor element that is responsible for a positive value and the second magnetoresistance effect element 20 as a memristor element that is responsible for a negative value. Further, as described above, a variation with temperature between the first magnetoresistance effect element 10 and the second magnetoresistance effect element 20 is small, and the neuromorphic device 1 can easily calculate weights for learning.

Further, in the neuromorphic device 1 according to the first embodiment, it is possible to reduce the number of transistors disposed in an integration area by the first magnetoresistance effect element 10 and the second magnetoresistance effect element 20 sharing the readout electrode 30. That is, the neuromorphic device 1 according to the first embodiment has an excellent integration property.

The embodiments of the present invention have been described in detail above, but the present invention is not limited to these embodiments.

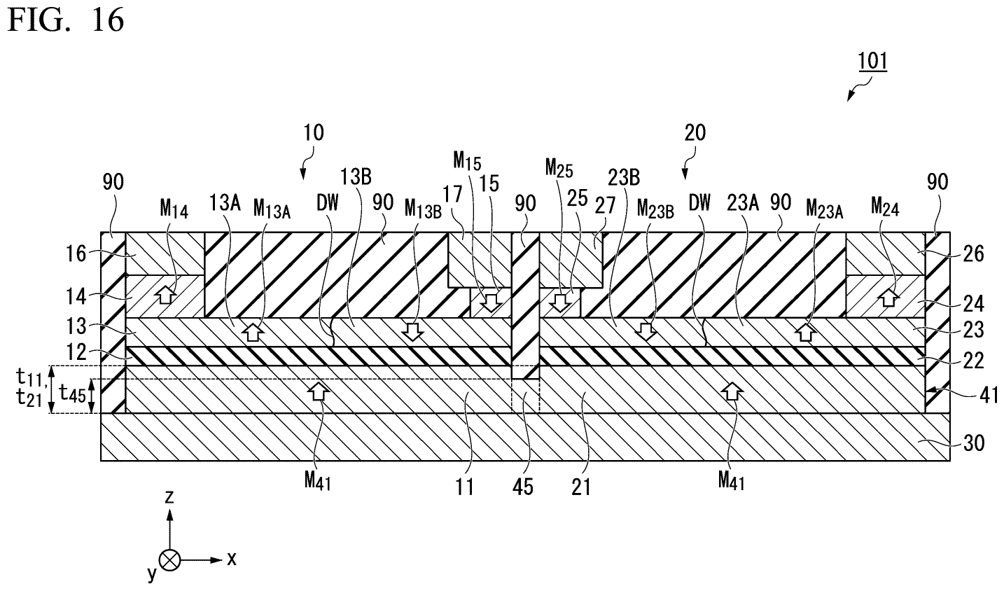

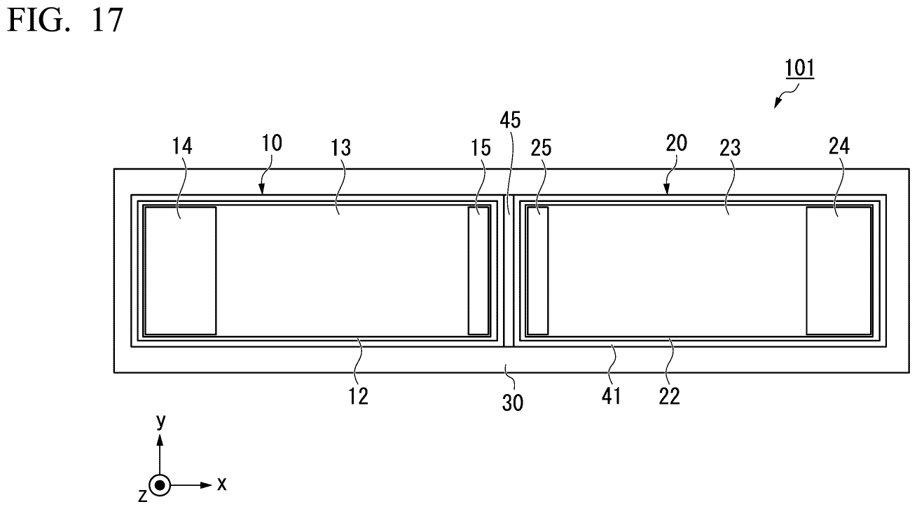

FIG. 16 is a cross-sectional view of a paired element 101 according to a first modification example. FIG. 16 illustrates a cross-section of the paired element 101 taken in an xz plane passing through a center in the y direction. FIG. 17 is a plan view of the paired element 101 according to the first modification example. In the paired element 101 according to the first modification example, the same components as those in the paired element 100 are denoted by the same reference signs and description thereof will be omitted.

The paired element 101 further includes a first connection portion 45 that connects the first reference layer 11 and the second reference layer 21. The first connection portion 45 is a portion that does not overlap with the first non-magnetic layer 12 and the second non-magnetic layer 22 when viewed from the z direction.

The first connection portion 45 is a ferromagnetic material. The first connection portion 45 is made of the same material as the first reference layer 11 and the second reference layer 21.

The first reference layer 11, the second reference layer 21, and the first connection portion 45 are magnetically coupled and function as an integrated reference layer 41. Magnetization M₄₁ of the reference layer 41 functions as an integrated portion. The first magnetoresistance effect element 10 and the second magnetoresistance effect element 20 also share the reference layer 41, so that a temperature variation between the first magnetoresistance effect element 10 and the second magnetoresistance effect element 20 can be further curbed.

A height t₄₅ of the first connection portion 45 in the z direction is smaller than a height t₁₁ of the first reference layer 11 and a height t₂₁ of the second reference layer 21. When the height of the first connection portion 45 is small, an influence of a leakage magnetic field from the first connection portion 45 on the first magnetic recording layer 13 and the second magnetic recording layer 23 is reduced, and an operation of the domain wall DW is stabilized.

As illustrated in FIG. 17, the reference layer 41 includes the first magnetic recording layer 13 and the second magnetic recording layer 23 when viewed from the z direction. When an area of the reference layer 41 is large, a heat capacity of the reference layer 41 is large, and heat exhaustion efficiency of the paired element 101 is improved. Further, the large area of the reference layer 41 also improves the stability of the magnetization M₄₁ of the reference layer 41.

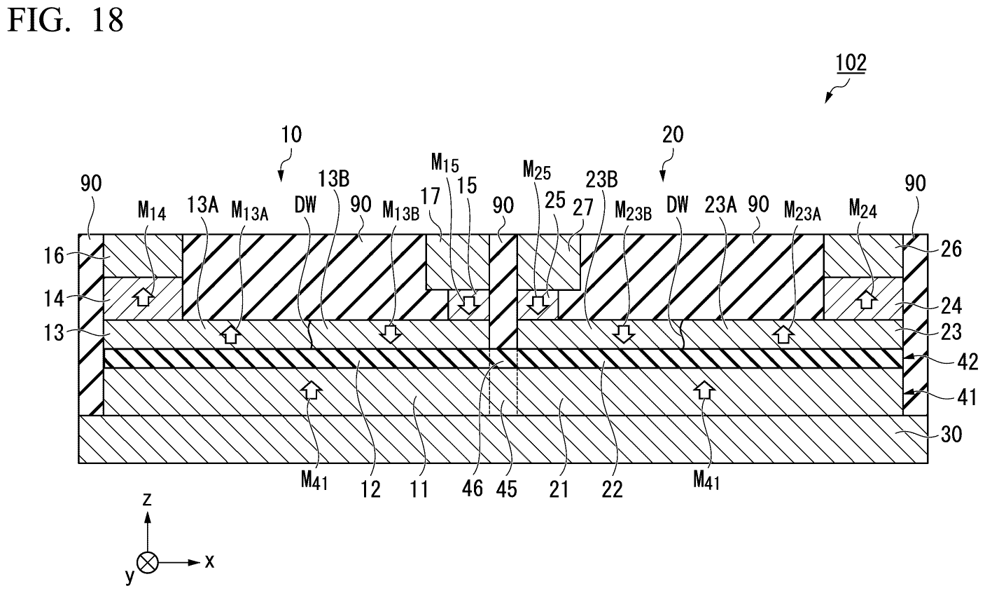

FIG. 18 is a cross-sectional view of a paired element 102 according to a second modification example. FIG. 18 illustrates a cross-section of the paired element 102 taken in an xz plane passing through a center in the y direction. In the paired element 102 according to the second modification example, the same components as those of the paired element 101 are denoted by the same reference signs and description thereof will be omitted.

The paired element 102 further includes a second connection portion 46 that connects the first non-magnetic layer 12 and the second non-magnetic layer 22. The second connection portion 46 is a portion that does not overlap with the first magnetic recording layer 13 and the second magnetic recording layer 23 when viewed from the z direction.

The second connection portion 46 is a non-magnetic material. The second connection portion 46 is made of the same material as the first non-magnetic layer 12 and the second non-magnetic layer 22.

The first non-magnetic layer 12, the second non-magnetic layer 22, and the second connection portion 46 form an integrated non-magnetic layer 42. The first magnetoresistance effect element 10 and the second magnetoresistance effect element 20 also share the non-magnetic layer 42, so that the temperature variation between the first magnetoresistance effect element 10 and the second magnetoresistance effect element 20 can be further curbed.

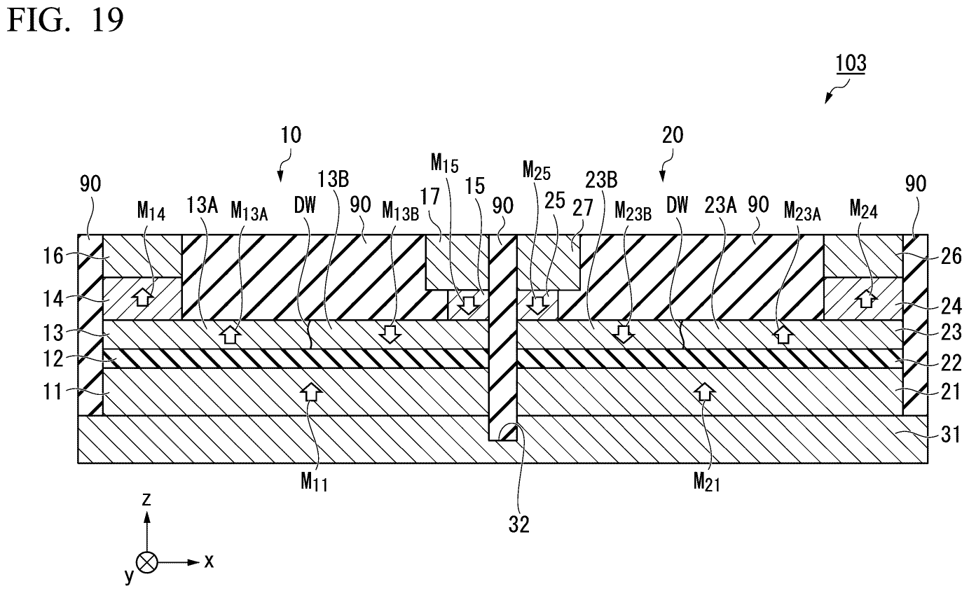

FIG. 19 is a cross-sectional view of a paired element 103 according to a third modification example. FIG. 19 illustrates a cross-section of the paired element 103 taken in an xz plane passing through a center in the y direction. In the paired element 103 according to the third modification example, the same components as those in the paired element 100 are denoted by the same reference signs and description thereof will be omitted.

In the paired element 103, a readout electrode 31 has a different shape from the readout electrode 30. The readout electrode 31 has a recess 32 in a surface that comes into contact with the first reference layer 11 and the second reference layer 21. The recess 32 is formed in a portion that does not overlap with the first reference layer 11 and the second reference layer 21 when viewed from the z direction. A film thickness of the readout electrode 31 in the portion in which the recess 32 has been formed is smaller than those of the other portions.

When the readout electrode 31 is shared between the first magnetoresistance effect element 10 and the second magnetoresistance effect element 20, the same effect as the paired element 100 can be obtained even when a thickness of a part of the readout electrode 31 is reduced.

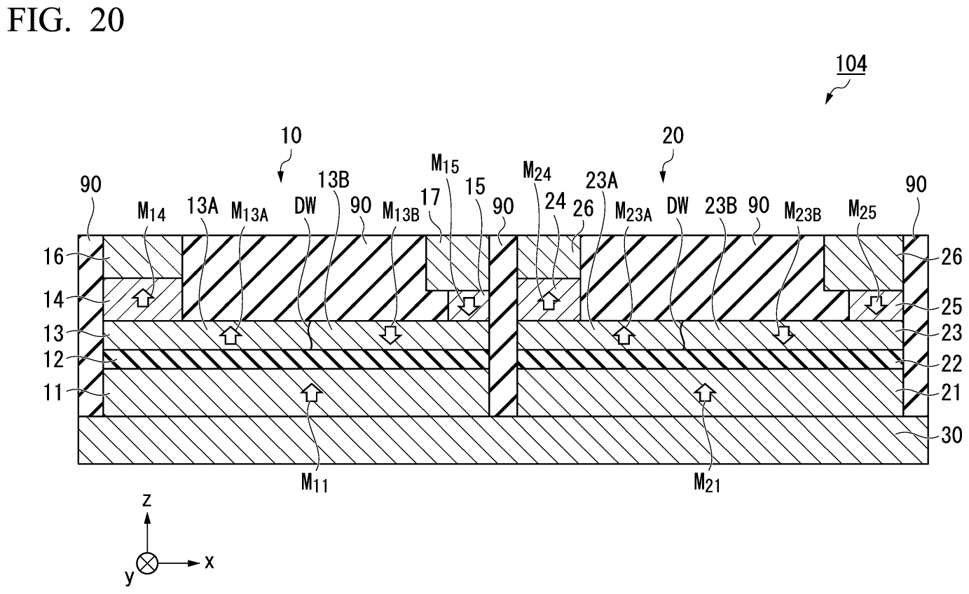

FIG. 20 is a cross-sectional view of a paired element 104 according to a fourth modification example. FIG. 20 illustrates a cross-section of the paired element 104 taken in an xz plane passing through a center in the y direction. In the paired element 104 according to the fourth modification example, the same components as those of the paired element 100 are denoted by the same reference symbols and description thereof will be omitted.

In the paired element 104 according to the fourth modification example, a positional relationship between the third magnetization fixing layer 24 and the fourth magnetization fixing layer 25 and a positional relationship between the third electrode 26 and the fourth electrode 27 are opposite to those of the paired element 100. A distance between the second magnetization fixing layer 15 and the third magnetization fixing layer 24 is smaller than a distance between the second magnetization fixing layer 15 and the fourth magnetization fixing layer 25. The distance between the second magnetization fixing layer 15 and the third magnetization fixing layer 24 having different magnetization orientation directions is small so that the magnetizations of the layers are magnetostatically stabilized.

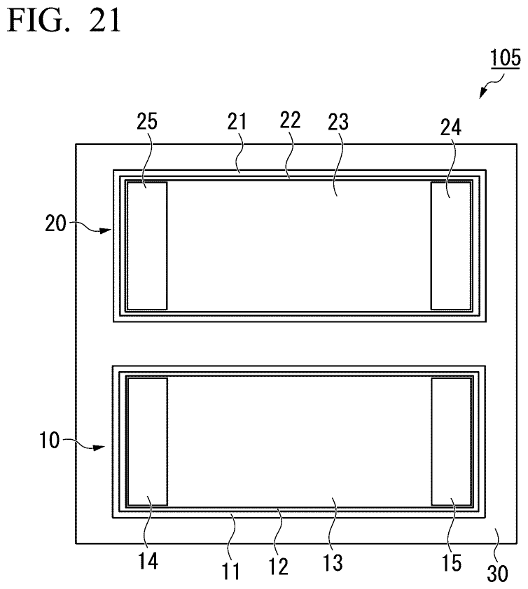

FIG. 21 is a plan view of the paired element 105 according to a fifth modification example. In the paired element 105 according to the fifth modification example, the same components as those in the paired element 100 are denoted by the same reference symbols and description thereof will be omitted.

In the fifth modification example, the first magnetoresistance effect element 10 and the second magnetoresistance effect element 20 belonging to the same paired element 105 are aligned in a direction (y direction) intersecting the longitudinal direction (x direction) of the first magnetoresistance effect element 10.

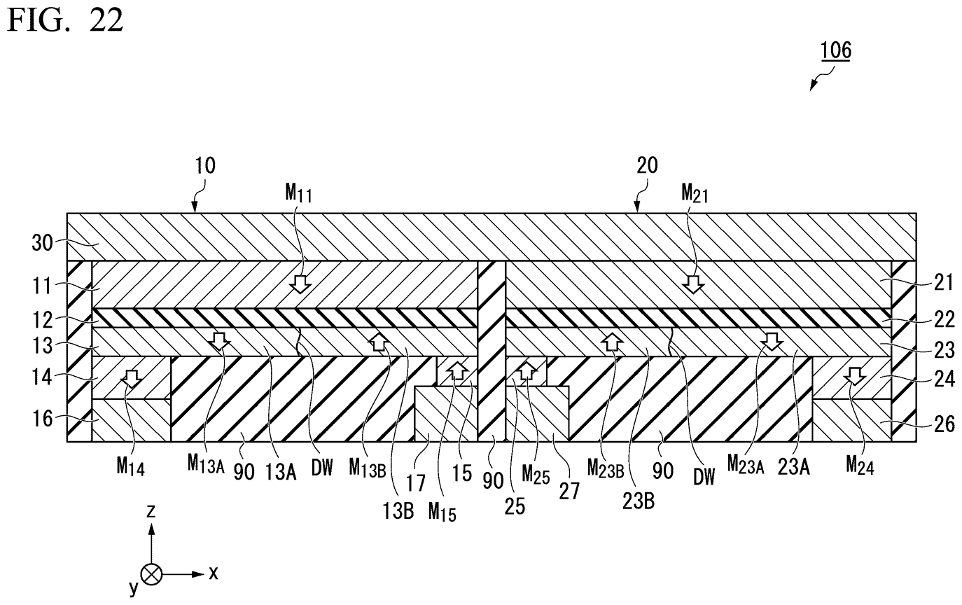

A paired element that is long in one direction is difficult to adjust to an exclusive area of the transistor, and is difficult to integrate. The paired element 104 with an aspect ratio close to 1 is easy to integrate within a predetermined area. FIG. 22 is a cross-sectional view of a paired element 106 according to a sixth modification example. FIG. 22 illustrates a cross section of the paired element 106 taken in the xz plane passing through the center in the y direction. In the paired element 106 according to the sixth modification example, the same components as those in the paired element 100 are denoted by the same reference symbols and description thereof will be omitted.

The paired element 106 has an opposite stacking order to the paired element 100. The first magnetic recording layer 13 is closer to the substrate Sub than the first reference layer 11. The second magnetic recording layer 23 is closer to the substrate Sub than the second reference layer 21. Such an element is called a top pin structure. In the top pin structure, the same effects as in the bottom pin structure can be obtained.

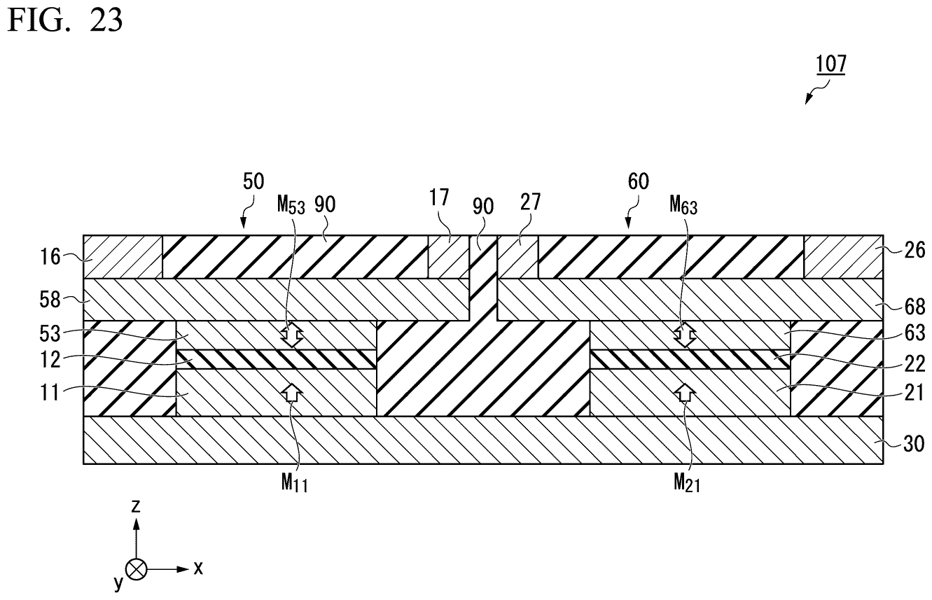

FIG. 23 is a cross-sectional view of the paired element 107 according to a seventh modification example. FIG. 23 illustrates a cross section of the paired element 107 taken in the xz plane passing through the center in the y direction. In the paired element 107 according to the seventh modification example, the same components as those in the paired element 100 are denoted by the same reference symbols and description thereof will be omitted.

The paired element 107 has a first magnetoresistance effect element 50, a second magnetoresistance effect element 60, and a readout electrode 30. The readout electrode 30 is shared by the first magnetoresistance effect element 50 and the second magnetoresistance effect element 60.

The first magnetoresistance effect element 50 includes the first reference layer 11, the first non-magnetic layer 12, a first magnetic recording layer 53, a first spin orbit torque line 58, the first electrode 16, and the second electrode 17.

The second magnetoresistance effect element 60 includes the second reference layer 21, the second non-magnetic layer 22, the second magnetic recording layer 63, the second spin orbit torque line 68, the third electrode 26, and the fourth electrode 27.

The first magnetic recording layer 53 and the second magnetic recording layer 63 are ferromagnetic materials. The first magnetic recording layer 53 and the second magnetic recording layer 63 are different from the first magnetic recording layer 13 and the second magnetic recording layer 23 of the paired element 100 in that the first magnetic recording layer 53 and the second magnetic recording layer 63 do not have a domain wall DW therein. Magnetization M₅₃ of the first magnetic recording layer 53 is reversed by spin injected from the first spin orbit torque line 58. Magnetization M₆₃ of the second magnetic recording layer 63 is reversed by spin injected from the second spin orbit torque line 68.

The first spin orbit torque line 58 generates a spin current using a spin Hall effect when a current flows in the x direction, and injects spin into the first magnetic recording layer 53. The second spin orbit torque line 68 generates a spin current using the spin Hall effect when a current flows in the x direction, and injects spin into the second magnetic recording layer 63. The first spin orbit torque line 58 and the second spin orbit torque line 68 include, for example, a heavy metal having a specific gravity equal to or greater than yttrium (Y).

The first magnetoresistance effect element 10 and the second magnetoresistance effect element 20 are each referred to as a spin orbit torque type magnetoresistance effect element. The first magnetoresistance effect element 10 and the second magnetoresistance effect element 20 can only express two values, but can be applied to, for example, devices that mimic a binary neural network. Further, the spin orbit torque type magnetoresistance effect element is an example of an element that does not have a domain wall, and other resistance change elements may also be applied. For example, a phase change memory (PCM) and a resistive random access memory (ReRAM) are examples of the resistance change element.

Several modification examples have been shown above, but these are also examples. Characteristic configurations thereof may be combined, and some may be changed without changing from the gist of the invention.

### REFERENCE SIGNS LIST

1 Neuromorphic device
2 Magnetic array
3 Control device
10, 50 First magnetoresistance effect element
11 First reference layer
12 First non-magnetic layer
13, 53 First magnetic recording layer
14 First magnetization fixing layer
15 Second magnetization fixing layer
16 First electrode
17 Second electrode
20, 60 Second magnetoresistance effect element
21 Second reference layer
22 Second non-magnetic layer
23, 63 Second magnetic recording layer
24 Third magnetization fixing layer
25 Fourth magnetization fixing layer
26 Third electrode
27 Fourth electrode
30 Readout electrode
41 Reference layer
42 Non-magnetic layer
45 First connection portion
46 Second connection portion
100, 101, 102, 103, 104, 105, 106 Paired element
C16, C17, C26, C27 Geometric center
DW Domain wall
IR1, IR2 Read current
L1, L2, L3 Distance
Sub Substrate

1. A neuromorphic device comprising a plurality of paired elements and a control device configured to control each of the plurality of paired elements, wherein
each of the plurality of paired elements includes a first magnetoresistance effect element, a second magnetoresistance effect element, and a readout electrode shared by the first magnetoresistance effect element and the second magnetoresistance effect element,
the first magnetoresistance effect element includes
a first reference layer,
a first magnetic recording layer,
a first non-magnetic layer between the first reference layer and the first magnetic recording layer,
a first electrode electrically connected to the first magnetic recording layer, and
a second electrode spaced apart from the first electrode and electrically connected to the first magnetic recording layer,
the second magnetoresistance effect element includes
a second reference layer,
a second magnetic recording layer,
a second non-magnetic layer between the second reference layer and the second magnetic recording layer,
a third electrode electrically connected to the second magnetic recording layer, and
a fourth electrode spaced apart from the third electrode and electrically connected to the second magnetic recording layer,
the readout electrode is connected across the first reference layer and the second reference layer,
the control device causes a first read current to flow in a stacking direction of the first magnetoresistance effect element to a specific paired element from which a signal is read and a second read current to flow in the stacking direction of the second magnetoresistance effect element to the specific paired element,
when the first read current flows from the first reference layer to the first magnetic recording layer, the second read current flows from the second magnetic recording layer to the second reference layer, and
when the first read current flows from the first magnetic recording layer to the first reference layer, the second read current flows from the second reference layer to the second magnetic recording layer.

2. The neuromorphic device according to claim 1, wherein the first magnetic recording layer and the second magnetic recording layer have domain walls therein.

3. The neuromorphic device according to claim 1, further comprising:
a substrate configured to support the plurality of paired elements, wherein
the first reference layer is closer to the substrate than the first magnetic recording layer, and
the second reference layer is closer to the substrate than the second magnetic recording layer.

4. The neuromorphic device according to claim 1, wherein
each of the plurality of paired elements further includes a first connection portion configured to connect the first reference layer to the second reference layer, and
the first reference layer, the second reference layer, and the first connection portion function as an integrated reference layer.

5. The neuromorphic device according to claim 4, wherein the reference layer in each of the plurality of paired elements includes the first magnetic recording layer and the second magnetic recording layer when viewed from the stacking direction.

6. The neuromorphic device according to claim 4, wherein a height of the first connection portion in the stacking direction is lower than those of the first reference layer and the second reference layer.

7. The neuromorphic device according to claim 4, wherein
each of the plurality of paired elements further includes a second connection portion configured to connect the first non-magnetic layer to the second non-magnetic layer, and
the first non-magnetic layer, the second non-magnetic layer, and the second connection portion function as an integrated non-magnetic layer.

8. The neuromorphic device according to claim 1, further comprising:
a first magnetization fixing layer between the first electrode and the first magnetic recording layer;
a second magnetization fixing layer between the second electrode and the first magnetic recording layer;
a third magnetization fixing layer between the third electrode and the second magnetic recording layer; and
a fourth magnetization fixing layer between the fourth electrode and the second magnetic recording layer, wherein
a magnetization orientation direction of the second magnetization fixing layer is opposite to magnetization orientation directions of the first magnetization fixing layer and the third magnetization fixing layer and is the same as the orientation direction of the fourth magnetization fixing layer, and
a distance between the second magnetization fixing layer and the third magnetization fixing layer is smaller than a distance between the second magnetization fixing layer and the fourth magnetization fixing layer.

9. The neuromorphic device according to claim 1, further comprising:
a first magnetization fixing layer between the first electrode and the first magnetic recording layer; and
a second magnetization fixing layer between the second electrode and the first magnetic recording layer, wherein
the magnetization orientation direction of the first magnetization fixing layer is opposite to that of the second magnetization fixing layer, and
a height of the first magnetization fixing layer in the stacking direction is different from a height of the second magnetization fixing layer in the stacking direction, or an area of the first magnetization fixing layer is different from an area of the second magnetization fixing layer as viewed from the stacking direction.

10. The neuromorphic device according to claim 1, wherein the first magnetoresistance effect element and the second magnetoresistance effect element belonging to the same paired element are aligned in a longitudinal direction of the first magnetoresistance effect element.

11. The neuromorphic device according to claim 1, wherein the first magnetoresistance effect element and the second magnetoresistance effect element belonging to the same paired element are aligned in a direction intersecting the longitudinal direction of the first magnetoresistance effect element.

12. The neuromorphic device according to claim 1, wherein a distance between the first magnetoresistance effect element and the second magnetoresistance effect element belonging to the same paired element is shorter than that between the first magnetoresistance effect element and the second magnetoresistance effect element belonging to a different paired element and that between the first magnetoresistance effect element and the first magnetoresistance effect element belonging to a different paired element.

13. The neuromorphic device according to claim 1, wherein
a current flows through the first electrode and the third electrode both when a signal is written and when a signal is read, and
a distance between the first electrode and the third electrode is longer than that between the second electrode and the fourth electrode.

14. The neuromorphic device according to claim 1, wherein at least two of geometric centers of the first electrode, the second electrode, the third electrode, and the fourth electrode belonging to the same paired element are at a position at which the readout electrode is sandwiched when viewed from the stacking direction.
